(19) United States
(12) Patent Application Publication
(10) Pub. No.: US 2026/0344150 A1
(43) Pub. Date: Oct. 29, 2026

(54) Display Device And Electronic Device

(71) Applicant: Samsung Display Co., Ltd., Yongin-si (KR)

(72) Inventors: Younggu Kang, Yongin-si (KR); Minji Kim, Yongin-si (KR); Hyeon-Do Park, Yongin-si (KR); Wondo Kim, Yongin-si (KR)

(73) Assignee: Samsung Display Co., Ltd., Yongin-si (KR)

(21) Appl. No.: 19/396,891

(22) Filed: Nov. 21, 2025

(30) Foreign Application Priority Data
Apr. 29, 2025 (KR) 10-2025-0056086

(51) Int. Cl. H10H 29/49; H10H 29/32

(52) U.S. Cl. CPC H10H 29/49; H10H 29/32

(57) ABSTRACT

A display device is provided that includes a display panel. The display panel includes display and non-display areas. The display area includes a corner portion. The display device includes a plurality of pixels disposed in the display area arranged in a grid defined by rows in a first direction and columns in a second direction, a first set of pixels from among the plurality of pixels being arranged in the corner portion and being disposed in a stepwise manner to define a shape of the corner portion , power connection lines disposed in the first direction in the non-display area, extending in the second direction from the non-display area to the corner portion, and transmitting power voltages to the pixels, and a connection pattern electrically connecting the power connection lines and extending in a direction away from the pixels adjacent to the connection pattern in the second direction.

This application claims priority to and the benefit of Korean Patent Application No. 10-2025-0056086, filed on Apr. 29, 2025, the disclosure of which is incorporated by reference herein in its entirety.

### TECHNICAL FIELD

The present disclosure relates to a display device that displays images, and an electronic device that includes the display device.

### BACKGROUND

A display device includes pixels that emit light and a driver that transmits a driving signal to the pixels. Each pixel includes a pixel driving circuit including a transistor and a light emitting element electrically connected to the pixel driving circuit. When a pulse potential due to an electrostatic discharge (ESD) generated in a line that transmits the driving signal to the pixels is introduced into the pixels, a device characteristic of the transistor included in the pixel driving circuit may change, thereby reducing the quality of the image displayed on the display device.

Accordingly, there is a need for display devices with improved image quality.

### BRIEF SUMMARY

The present disclosure is intended to solve problems including problems associated with image quality. The present disclosure describes a display device with improved image quality, and an electronic device that includes the contemplated display device.

However, aspects of the present disclosure are not restricted to those set forth herein. The above and other aspects of the present disclosure will become apparent to one of ordinary skill in the art to which the present disclosure pertains by referencing the detailed description of the present disclosure given below.

According to some aspects, a display device is provided that comprises: a display panel comprising a display area and a non-display area adjacent to the display area, the display area including a corner portion, a plurality of pixels disposed in a display area arranged in a grid defined by rows in a first direction and columns in a second direction crossing the first direction, power connection lines disposed in the first direction in the non-display area, extending in the second direction from the non-display area to the corner portion, and transmitting power voltages to the pixels, and a connection pattern electrically connecting the power connection lines and extending in a direction away from the pixels adjacent to the connection pattern in the second direction. In the corner portion, a first set of pixels of the plurality of pixels are disposed in a stepwise manner to define a shape of the corner portion.

In some aspects, the power connection lines comprise a first power connection line transmitting a first power voltage, a second power connection line transmitting the first power voltage, and a third power connection line transmitting a second power voltage. In some aspects, the connection pattern is connected to the first power connection line and the second power connection line, and the connection pattern at least partially overlaps each of the first power connection line, the second power connection line, and the third power connection line.

In some aspects, the display device further comprises a power connection pattern adjacent to the power connection lines in the first direction. In some aspects, the connection pattern electrically connects the power connection lines to the power connection pattern.

In some aspects, the connection pattern includes a first connection pattern and a second connection pattern disposed in different layers.

In some aspects, the first connection pattern is connected to the power connection pattern, and the second connection pattern is connected to the power connection lines and the first connection pattern.

In some aspects, each of the pixels comprise an active pattern, a first gate electrode disposed on the active pattern, a capacitor electrode disposed on the first gate electrode, a second gate electrode disposed on the capacitor electrode, and a source electrode disposed on the second gate electrode. In some aspects, the first connection pattern and the first gate electrode are disposed in a same layer. In some aspects, the second connection pattern and the source electrode are disposed in a same layer.

In some aspects, each of the pixels comprise an active pattern, a first gate electrode disposed on the active pattern, a capacitor electrode disposed on the first gate electrode, a second gate electrode disposed on the capacitor electrode, and a source electrode disposed on the second gate electrode. In some aspects, the connection pattern and the source electrode are disposed in a same layer.

In some aspects, the connection pattern comprises a shape curved in a direction opposite to the second direction. For example, the connection pattern comprises a U-shaped curve in a direction opposite to the second direction.

In some aspects, in the corner portion, the pixels comprise first pixels disposed in a first row, second pixels disposed in a second row, and third pixels disposed in a third row. In some aspects, the power connection lines extend to the third row, and the power connection lines are spaced apart from the second row.

In some aspects, the display device may further include gate connection lines extending in the first direction from the display area to the non-display area, the gate connection lines transmitting gate signals to the pixels. The gate connection lines may include a first gate connection line electrically connected to the first pixels, a second gate connection line electrically connected to the second pixels, and a third gate connection line electrically connected to the third pixels. The second gate connection line may extend further to the non-display area than the third gate connection line.

In some aspects, an end portion of the first gate connection line and an end portion of the second gate connection line may be disposed in the second direction.

In some aspects, a display device is provided that comprises: a display panel comprising a display area and a non-display area adjacent to the display area, the display area including a corner portion, a plurality of pixels disposed in the display area in a grid defined by rows in a first direction and columns in a second direction crossing the first direction, power connection lines disposed in the first direction in the non-display area and transmitting power voltages to the pixels. In the corner portion, a first set of pixels of the plurality of pixels are disposed in a stepwise manner to define a shape of the corner area, and include first pixels disposed in a first row, second pixels disposed in a second row, and third pixels disposed in a third row. The power connection lines extend in the second direction from the non-display area to the third row of the corner portion.

In some aspects, the power connection lines are spaced apart from the second row.

In some aspects, the display device further comprises gate connection lines extending in the first direction from the display area to the non-display area and transmitting gate signals to the pixels.

In some aspects, the gate connection lines comprises a first gate connection line electrically connected to the first pixels, a second gate connection line electrically connected to the second pixels, and a third gate connection line electrically connected to the third pixels. The second gate connection line extends to the non-display area further than the third gate connection line extends to the non-display area.

In some aspects, an end portion of the first gate connection line and an end portion of the second gate connection line are disposed in the second direction.

In some aspects, the display device further comprise a connection pattern electrically connecting the power connection lines.

In some aspects, the connection pattern extends in a direction away from the pixels adjacent to the connection pattern in the second direction.

In some aspects, the power connection lines comprise a first power connection line transmitting a first power voltage, a second power connection line transmitting the first power voltage, and a third power connection line transmitting a second power voltage. In some aspects, the connection pattern is connected to the first power connection line and the second power connection line, and the connection pattern at least partially overlap each of the first power connection line, the second power connection line, and the third power connection line.

In some aspects, an electronic device is provided that comprises: a display device including pixels, and a processor providing a control signal and input image data to the display device. The display device includes a display panel comprising a display area and a non-display area adjacent to the display area. The display area includes a corner portion. A plurality of pixels are disposed in the display area, the pixels being arranged in a grid defined by rows in a first direction and columns in a second direction crossing the first direction. The display device includes power connection lines disposed in the first direction in the non-display area, extending in the second direction from the non-display area to the corner portion, and transmitting power voltages to the pixels. In some aspects, a connection pattern electrically connects the power connection lines and extends in a direction away from the pixels adjacent to the connection pattern in the second direction. In the corner portion, a first set of pixels of the plurality of pixels are disposed in a stepwise manner to define a shape of the corner portion.

In some aspects, the display device comprises the power connection lines that transmit the power voltages to the pixels and the connection pattern that electrically connects the power connection lines that transmit the power voltages. In some aspects, the connection pattern extends in a direction away from the pixels in the corner portion. In some aspects, the power connection lines are disposed to be spaced apart from the pixels in the corner portion. Therefore, the introduction of the pulse potential caused by electrostatic discharge generated in the power connection lines into the pixels is reduced, so that malfunctions of the pixel driving circuit are reduced or prevented. As such, a display quality of the display device is improved.

Advantages of the display device of the present disclosure are not limited to those mentioned above and various other effects are described in the detailed description below.

### BRIEF DESCRIPTION OF THE DRAWINGS

The above and other aspects and features of the present disclosure will become apparent by describing in detail embodiments thereof with reference to the attached drawings, in which:

FIG. 1 is a block diagram illustrating a display device according to an embodiment of the present disclosure;

FIG. 2 is a plan view illustrating the display device of FIG. 1;

FIG. 3 is an equivalent circuit diagram illustrating a pixel included in the display device of FIG. 1;

FIG. 4 is a cross-sectional view illustrating a display panel included in the display device of FIG. 1;

FIG. 5 is an enlarged plan view illustrating area A of FIG. 2;

FIGS. 6 to 8 are enlarged plan views illustrating area B of FIG. 5;

FIG. 9 is a plan view illustrating a display device according to an embodiment of the present disclosure;

FIG. 10 is a plan view illustrating a display device according to an embodiment of the present disclosure;

FIG. 11 is a block diagram illustrating an electronic device according to an embodiment of the present disclosure; and

FIG. 12 is a schematic diagram illustrating electronic devices according to various embodiments of the present disclosure.

### DETAILED DESCRIPTION

While specific embodiments are shown in the drawings and described in detail herein below, the present disclosure may be modified in a variety of ways and realized in many different forms. Accordingly, it will be appreciated that the present disclosure is not limited to the specific disclosed forms, and should be construed to include all modifications, equivalents, or replacements included within the spirit and scope of the present disclosure.

In the drawings, sizes and relative sizes of components, layers and regions may be exaggerated or reduced for clarity. For example, a size and thickness of each component shown in the drawing are arbitrarily shown for convenience of explanation, and thus the present implementation of the teachings of the present disclosure are not necessarily limited to what is shown. When describing with reference to the drawings, identical or corresponding components are given the same reference numerals and redundant descriptions thereof are omitted.

In the disclosure, various modifications can be made, various forms can be used, and specific embodiments will be illustrated in the drawings and described in detail in the text. However, this is not intended to limit the disclosed subject matter to specific disclosed embodiments, and it will be understood to those skilled in the art that changes, equivalents, or substitutes are possible therefrom.

It is to be understood that, although the terms “first”, “second”, “third”, etc. may be used herein to describe various elements, these elements should not be limited by these terms. These terms are used to distinguish one element from another element. For instance, a first element discussed below could be termed a second element without departing from the teachings of the present disclosure. Similarly, the second element could also be termed a first element.

As used herein, the term “and/or” includes any and all combinations of one or more of the associated listed items. For example, in the present disclosure, “A and/or B” refers to either A, B, or both A and B, and “at least one of A and B” indicates the case where it is A, or B, or both A and B.

It is also to be understood that when an element is referred to as being “on”, “connected to” or “coupled to” to another element, it can be directly disposed on/connected to/coupled to the other element or intervening element(s) may be present therebetween. In contrast, when an element is referred to as being “directly on”, “directly connected to” or “directly coupled to” to another element, there are no intervening elements present. Other words used to describe the relationship between elements should be interpreted in a like fashion (e.g., “between” versus “directly between,” “adjacent” versus “directly adjacent,” etc.).

Additionally, the terms “about,” “generally,” and “substantially” are intended to mean, and a person of ordinary skill would understand them to mean that slight deviations from absolute are included within the scope of the term so modified.

The x-axis, y-axis, and z-axis are not limited to the three axes on the orthogonal coordinate system and may be interpreted in a broad sense that includes them. For example, the x-axis, y-axis, and z-axis may be orthogonal to each other, but they may also refer to different directions that are not orthogonal to each other.

In some aspects, a display device may be included in various electronic devices. In some aspects, an electronic device according includes the display device described above, and may further include a module or device having additional functions in addition to the display device.

In addition, the terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terminology used herein is for the purpose of describing particular example embodiments only and is not intended to be limiting of the present inventive concept.

As used herein, singular expressions, such as “a,” “an” and “the” are intended to include the plural expressions, unless the context clearly indicates otherwise.

It is also to be further understood that the terms “comprises/includes” and/or “comprising/including”, when used in this specification, specify the presence of stated features, integers, steps, operations, elements, and/or components, but do not preclude the presence or addition of one or more other features, integers, steps, operations, elements, components, and/or groups thereof.

Furthermore, relative terms, such as “lower” or “bottom” and “upper” or “top” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the accompanying drawings. The same reference numerals are used for the same components in the drawings, and redundant descriptions of the same components will be omitted.

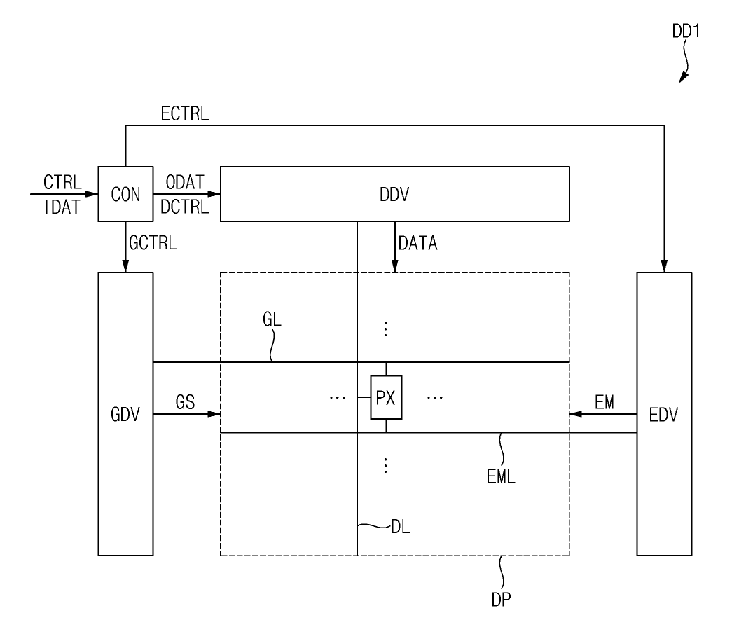

FIG. 1 is a block diagram illustrating a display device according to an embodiment.

Referring to FIG. 1, a display device DD1 may include a display panel DP and a driver for driving the display panel DP. The driver may include a controller CON, a gate driver GDV, an emission driver EDV, and a data driver DDV.

The display panel DP may include pixels PX, gate lines GL, emission lines EML, and data lines DL. Each of the pixels PX may be electrically connected to the gate driver GDV, the emission driver EDV, and the data driver DDV, and may generate light according to a driving signal.

The gate driver GDV may receive a gate control signal GCTRL from the controller CON. The gate driver GDV may generate gate signals GS based on the gate control signal GCTRL. The gate driver GDV may provide the gate signals GS to the pixels PX through the gate lines GL.

The emission driver EDV may receive an emission control signal ECTRL from the controller CON. The emission driver EDV may generate emission signals EM based on the emission control signal ECTRL. The emission driver EDV may provide the emission signals EM to the pixels PX through the emission lines EML.

The data driver DDV may receive a data control signal DCTRL and output image data ODAT from the controller CON. The data driver DDV may generate data voltages DATA based on the data control signal DCTRL and the output image data ODAT. The data driver DDV may provide the data voltages DATA to the pixels PX through the data lines DL.

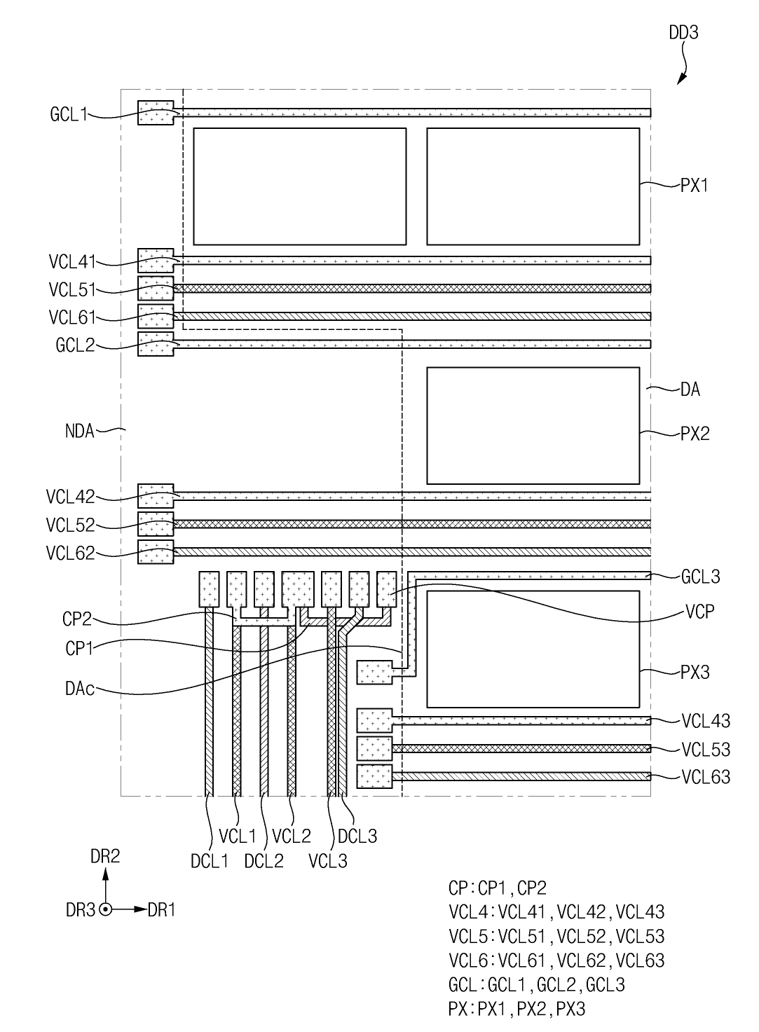

The controller CON may receive a control signal CTRL and input image data IDAT from an external device (e.g., a processor 12 of FIG. 10). The controller CON may generate the gate control signal GCTRL, the emission control signal ECTRL, the data control signal DCTRL, and the output image data ODAT based on the control signal CTRL and the input image data IDAT. The controller CON may control the gate driver GDV, the emission driver EDV, and the data driver DDV.

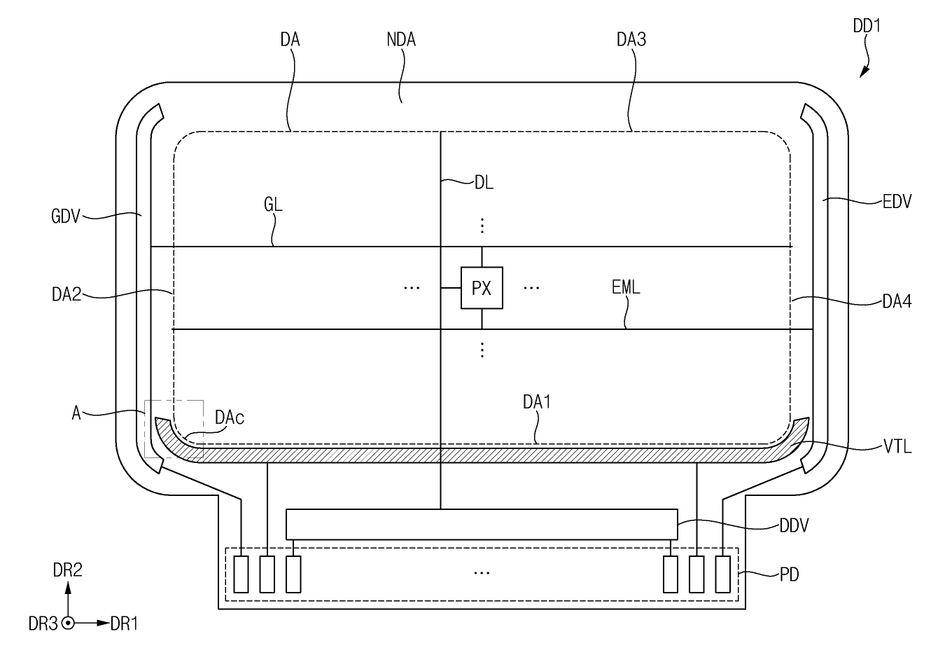

FIG. 2 is a plan view illustrating the display device of FIG. 1.

Referring to FIGS. 1 and 2, the display device DD1 may include the display panel DP, the gate driver GDV, the emission driver EDV, the data driver DDV, a power transmission line VTL, and pads PD. The display panel DP may include a display area DA and a non-display area NDA.

The display area DA may be an area capable of displaying an image. The pixels PX may be disposed in the display area DA. The pixel area DA may include a plurality of pixels PX disposed in the display area DA. The plurality of pixels PX may be arranged in a grid defined by rows in a first direction DR1 and columns in a second direction DR2 crossing the first direction. A first set of pixels from among the plurality of pixels may be arranged in the corner portion and disposed in a stepwise manner to define a shape of the corner portion DAc (described below). For example, the pixels PX may be repeatedly disposed in the first direction DR1 and the second direction DR2 crossing the first direction DR1. As each of the pixels PX emits light, the display area DA may display the image. For example, the display area DA may display the image in a third direction DR3 crossing each of the first direction DR1 and the second direction DR2.

In an embodiment, the display area DA may have a planar shape rather than a rectangular planar shape with right-angled corners. For example, the display area DA may have a rectangular planar shape with rounded corners. For example, the display area DA may have a rectangular planar shape with rounded corners, where long sides extend in the first direction DR1 and short sides extend in the second direction DR2. However, embodiments are not limited thereto, and the display area DA may have various planar shapes that have curved portion.

In an embodiment, the display area DA may include a first side DA1, a second side DA2, a third side DA3, a fourth side DA4, and corner portions DAc having a rounded shape in a plan view. The first side DA1 and the third side DA3 may be opposite to each other and may each extend in the first direction DR1. The second side DA2 and the fourth side DA4 may be opposite to each other and may extend in the second direction DR2.

Each corner portion DAc may be defined between two adjacent sides among the first to fourth sides DA1, DA2, DA3, and DA4. The corner portions DAc may connect the first side DA1 and the second side DA2, the second side DA2 and the third side DA3, the third side DA3 and the fourth side DA4, and the fourth side DA4 and the first side DA1.

The non-display area NDA may be an area that does not display an image. The non-display area NDA may be adjacent to the display area DA. For example, the non-display area NDA may surround the display area DA in a plan view. The driver may be disposed in the non-display area NDA. For example, the gate driver GDV, the emission driver EDV, the data driver DDV, the power transmission line VTL, and the pads PD may be disposed in the non-display area NDA.

For example, the gate driver GDV may be disposed in the non-display area NDA adjacent to the second side DA2 (e.g., a left side) of the display area DA, and the emission driver EDV may be disposed in the non-display area NDA adjacent to the fourth side DA4 (e.g., a right side) of the display area DA. The gate driver GDV may output the gate signals GS to the gate lines GL, and the gate signals GS may be applied to the pixels PX through the gate lines GL. The emission driver EDV may output the emission signals EM to the emission lines EML, and the emission signals EM may be applied to the pixels PX through the emission lines EML.

FIG. 2 illustrates that the gate driver GDV is disposed on a first side portion of the display device DD1 and the emission driver EDV is disposed on a second side portion of the display device DD1, but embodiments are not limited thereto. For example, the gate driver GDV and the emission driver EDV may be disposed together on the first side portion or the second side portion of the display device DD1. For example, the gate driver GDV and the emission driver EDV may be integrally formed.

For example, the data driver DDV may be disposed in the non-display area NDA adjacent to the first side DA1 (e.g., a lower side) of the display area DA. The data driver DDV may output the data voltages DATA to the data lines DL, and the data voltages DATA may be applied to the pixels PX through the data lines DL.

For example, the power transmission line VTL may be disposed in the non-display area NDA adjacent to the first side DA1 (e.g., the lower side) of the display area DA. The power transmission line VTL may be disposed between the display area DA and the data driver DDV in a plan view.

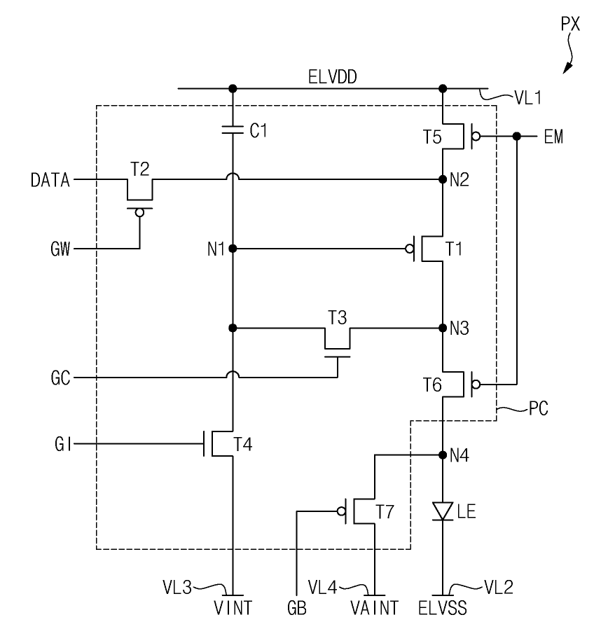

The power transmission line VTL may output a power voltage (e.g., a constant voltage) to a power line, and the power voltage may be applied to the pixels PX through the power line. In an embodiment, the power transmission line VTL may include a plurality of power transmission lines. For example, the power transmission line VTL may include a first power transmission line to which a first power voltage (e.g., the first power voltage ELVDD of FIG. 3) is applied, a second power transmission line to which a second power voltage (e.g., the second power voltage ELVSS of FIG. 3) is applied, a third power transmission line to which a first initialization voltage (e.g., the first initialization voltage VINT of FIG. 3) is applied, and a fourth power transmission line to which a second initialization voltage (e.g., the second initialization voltage VAINT of FIG. 3) is applied.

The power transmission line VTL may extend along a planar profile of the display area DA in the non-display area NDA. In an embodiment, an end portion of the power transmission line VTL may extend along the corner portion DAc. In order to provide the power voltage to the pixels PX disposed in an area adjacent to the corner portion DAc, the end portion of the power transmission line VTL may extend between the gate driver GDV and the display area DA or between the emission driver EDV and the display area DA along the corner portion DAc. That is, the power transmission line VTL may have a shape in which the end portion is bent along a planar shape (e.g., a rounded planar shape) of the corner portion DAc. For example, a first end portion of the power transmission line VTL may extend along a rounded planar shape of the corner portion DAc defined between the first side DA1 and the second side DA2, and a second end portion of the power transmission line VTL may extend along a rounded planar shape of the corner portion DAc defined between the first side DA1 and the third side DA3.

For example, the pads PD may be disposed in the non-display area NDA adjacent to the first side DA1 (e.g., the lower side) of the display area DA. The pads PD may be electrically connected to the gate driver GDV, the emission driver EDV, the data driver DDV, and the power transmission line VTL.

FIG. 3 is an equivalent circuit diagram illustrating a pixel included in the display device of FIG. 1.

Referring to FIG. 3, the pixel PX may include a light emitting element LE and a pixel driving circuit PC electrically connected to the light emitting element LE. The pixel driving circuit PC may generate a driving current, and the light emitting element LE may generate light based on the driving current.

The pixel driving circuit PC may include at least one transistor and at least one capacitor. In an embodiment, the pixel driving circuit PC may include a first transistor T1, a second transistor T2, a third transistor T3, a fourth transistor T4, a fifth transistor T5, a sixth transistor T6, a seventh transistor T7, and a capacitor C1.

The pixel driving circuit PC may be connected to a first power line VL1, a second power line VL2, a third power line VL3, and a fourth power line VL4. The first power line VL1 may transmit the first power voltage ELVDD, and the second power line VL2 may transmit the second power voltage ELVSS. A voltage level of the first power voltage ELVDD may be higher than a voltage level of the second power voltage ELVSS. The third power line VL3 may transmit the first initialization voltage VINT, and the fourth power line VL4 may transmit the second initialization voltage VAINT.

The first transistor T1 may include a gate electrode connected to a first node N1, a first electrode connected to a second node N2, and a second electrode connected to a third node N3. The first transistor T1 may provide the driving current to the light emitting element LE. For example, the first transistor T1 may be referred to as a driving transistor.

The second transistor T2 may include a gate electrode receiving a first gate signal GW, a first electrode receiving the data voltage DATA, and a second electrode connected to the second node N2. The second transistor T2 may provide the data voltage DATA to the second node N2 in response to the first gate signal GW. For example, the second transistor T2 may be referred to as a write transistor.

The third transistor T3 may include a gate electrode receiving a second gate signal GC, a first electrode connected to the first node N1, and a second electrode connected to the third node N3. The third transistor T3 may diode-connect the first transistor T1 in response to the second gate signal GC. The third transistor T3 may form a path that compensates for a threshold voltage of the first transistor T1. For example, the third transistor T3 may be referred to as a compensation transistor.

The fourth transistor T4 may include a gate electrode receiving a third gate signal GI, a first electrode receiving the first initialization voltage VINT, and a second electrode connected to the first node N1. The fourth transistor T4 may provide the first initialization voltage VINT to the first node N1 in response to the third gate signal GI. The fourth transistor T4 may provide the first initialization voltage VINT to the gate electrode of the first transistor T1 to initialize the voltage of the gate electrode of the first transistor T1. For example, the fourth transistor T4 may be referred to as a gate initialization transistor.

The fifth transistor T5 may include a gate electrode receiving the emission signal EM, a first electrode receiving the first power voltage ELVDD, and a second electrode connected to the second node N2. The fifth transistor T5 may provide the first power voltage ELVDD to the second node N2 in response to the emission signal EM. For example, the fifth transistor T5 may be referred to as a first emission control transistor.

The sixth transistor T6 may include a gate electrode receiving the emission signal EM, a first electrode connected to the third node N3, and a second electrode connected to a fourth node N4. The sixth transistor T6 may electrically connect the second electrode of the first transistor T1 and a first electrode of the light emitting element LE in response to the emission signal EM. For example, the sixth transistor T6 may be referred to as a second emission control transistor.

FIG. 3 illustrates that the fifth transistor T5 and the sixth transistor T6 are substantially simultaneously driven by the single emission signal EM, but embodiments are not limited thereto. For example, the fifth transistor T5 and the sixth transistor T6 may be independently driven by different emission signals.

The seventh transistor T7 may include a gate electrode receiving a fourth gate signal GB, a first electrode receiving the second initialization voltage VAINT, and a second electrode connected to the fourth node N4. The seventh transistor T7 may provide the second initialization voltage VAINT to the fourth node N4 in response to the fourth gate signal GB. The seventh transistor T7 may provide the second initialization voltage VAINT to the first electrode of the light emitting element LE to initialize a voltage of the first electrode of the light emitting element LE. For example, the seventh transistor T7 may be referred to as an anode initialization transistor.

The capacitor C1 may include a first electrode receiving the first power voltage ELVDD and a second electrode connected to the first node N1. For example, the capacitor C1 may be referred to as a storage capacitor.

The light emitting element LE may include the first electrode connected to the fourth node N4 and a second electrode receiving the second power voltage ELVSS. The light emitting element LE may generate light with a brightness corresponding to the driving current.

FIG. 3 illustrates that each of the first, second, fifth, sixth, and seventh transistors T1, T2, T5, T6, and T7 is a p-type transistor, and each of the third and fourth transistors T3, T4 is an n-type transistor, but embodiments are not limited thereto. For example, all of the first to seventh transistors T1, T2, T3, T4, T5, T6, and T7 may be p-type transistors, or at least one of the first to seventh transistors T1, T2, T3, T4, T5, T6, and T7 may be an n-type transistor.

In addition, FIG. 3 illustrates that the pixel driving circuit PC includes seven transistors and one capacitor, but embodiments are not limited thereto.

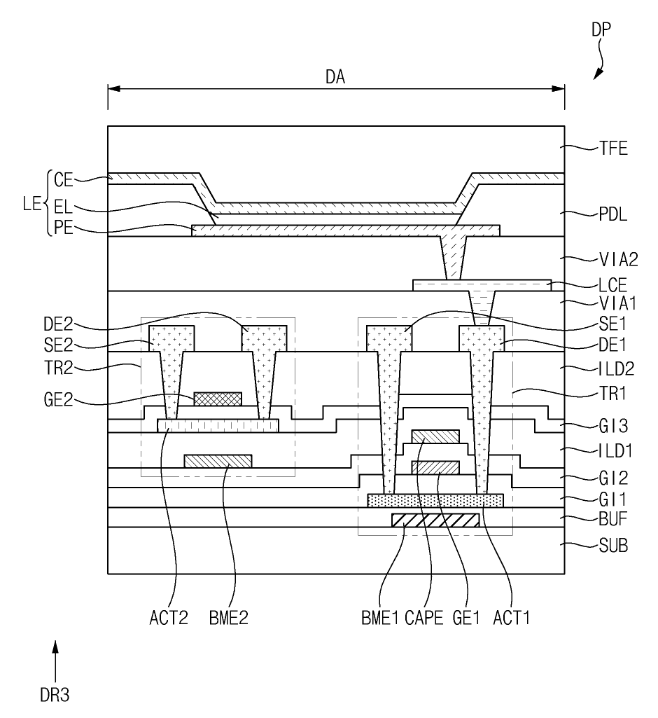

FIG. 4 is a cross-sectional view illustrating a display panel included in the display device of FIG. 1.

Referring to FIG. 4, the display panel DP may include a substrate SUB, a buffer layer BUF, a first transistor TR1, a first gate insulating layer GI1, a second gate insulating layer GI2, a capacitor electrode CAPE, a second transistor TR2, a first interlayer insulating layer ILD1, a second interlayer insulating layer ILD2, a first via insulating layer VIA1, a connection electrode LCE, a second via insulating layer VIA2, the light emitting element LE, a pixel defining layer PDL, and an encapsulation layer TFE.

The first transistor TR1 may include a first lower electrode BME1, a first active pattern ACT1, a first gate electrode GE1, a first source electrode SE1, and a first drain electrode DE1. The second transistor TR2 may include a second lower electrode BME2, a second active pattern ACT2, a second gate electrode GE2, a second source electrode SE2, and a second drain electrode DE2. The light emitting element LE may include a pixel electrode PE, an emission layer EL, and a common electrode CE.

The first transistor TR1 may be a transistor that is connected to the light emitting element LE through the connection electrode LCE. For example, the first transistor TR1 may be the sixth transistor T6 of FIG. 3, and the second transistor TR2 may be the third transistor T3 or the fourth transistor T4 of FIG. 3.

The substrate SUB may form a base of the display panel DP. The substrate SUB may include a transparent or opaque material. For example, the substrate SUB may include plastic, glass, quartz, silicon, or the like.

The first lower electrode BME1 may be disposed on the substrate SUB. The first lower electrode BME1 may include a conductive material, such as a metal, an alloy, a conductive metal nitride, a conductive metal oxide, a transparent conductive oxide, or the like. In an embodiment, the first lower electrode BME1 may be omitted.

The buffer layer BUF may be disposed on the first lower electrode BME1, and may cover the first lower electrode BME1. The buffer layer BUF may include an inorganic insulating material, such as silicon oxide (SiOₓ), silicon nitride (SiNₓ), silicon oxynitride (SiOₓN_{y}), or the like. In an embodiment, the buffer layer BUF may be omitted.

The first active pattern ACT1 may be disposed on the buffer layer BUF. The first active pattern ACT1 may at least partially overlap the first lower electrode BME1 in a plan view. The first active pattern ACT1 may include a first source area, a first drain area, and a first channel area between the first source area and the first drain area. The first active pattern ACT1 may include a semiconductor material, such as a silicon semiconductor material, an oxide semiconductor material, or the like. Examples of the silicon semiconductor material may include amorphous silicon, polycrystalline silicon, or the like. Examples of the oxide semiconductor material may include indium gallium zinc oxide (IGZO), indium tin zinc oxide (ITZO), or the like. In an embodiment, the first active pattern ACT1 may include the silicon semiconductor material.

The first gate insulating layer GI1 may be disposed on the first active pattern ACT1, and may cover the first active pattern ACT1. The first gate insulating layer GI1 may include an inorganic insulating material.

The first gate electrode GE1 may be disposed on the first gate insulating layer GI1. The first gate electrode GE1 may overlap the first channel area of the first active pattern ACT1 in a plan view. The first gate electrode GE1 may include a conductive material.

The second gate insulating layer GI2 may be disposed on the first gate electrode GE1, and may cover the first gate electrode GE1. The second gate insulating layer GI2 may include an inorganic insulating material.

The capacitor electrode CAPE and the second lower electrode BME2 may be disposed on the second gate insulating layer GI2. The capacitor electrode CAPE may overlap the first gate electrode GE1 in a plan view. For example, the capacitor electrode CAPE and the first gate electrode GE1 may form the capacitor C1 of FIG. 3. The capacitor electrode CAPE and the second lower electrode BME2 may include a conductive material. In an embodiment, the second lower electrode BME2 may be omitted.

The first interlayer insulating layer ILD1 may be disposed on the capacitor electrode CAPE and the second lower electrode BME2, and may cover the capacitor electrode CAPE and the second lower electrode BME2. The first interlayer insulating layer ILD1 may include an inorganic insulating material.

The second active pattern ACT2 may be disposed on the first interlayer insulating layer ILD1. The second active pattern ACT2 may at least partially overlap the second lower electrode BME2 in a plan view. The second active pattern ACT2 may include a second source area, a second drain area, and a second channel area between the second source area and the second drain area. The second active pattern ACT2 may include a semiconductor material. In an embodiment, the second active pattern ACT2 may include an oxide semiconductor material.

The third gate insulating layer GI3 may be disposed on the second active pattern ACT2, and may cover the second active pattern ACT2. The third gate insulating layer GI3 may include an inorganic insulating material.

The second gate electrode GE2 may be disposed on the third gate insulating layer GI3. The second gate electrode GE2 may overlap the second channel area of the second active pattern ACT2 in a plan view. The second gate electrode GE2 may include a conductive material.

The second interlayer insulating layer ILD2 may be disposed on the second gate electrode GE2, and may cover the second gate electrode GE2. The second interlayer insulating layer ILD2 may include an inorganic insulating material.

The first source electrode SE1, the first drain electrode DE1, the second source electrode SE2, and the second drain electrode DE2 may be disposed on the second interlayer insulating layer ILD2.

The first source electrode SE1 may be electrically connected to the first source area of the first active pattern ACT1 through a first contact hole that penetrates an insulating layer (e.g., the first to third gate insulating layers GI1, GI2, and GI3 and the first and second interlayer insulating layers ILD1 and ILD2) disposed therebelow. The first drain electrode DE1 may be electrically connected to the first drain area of the first active pattern ACT1 through a second contact hole that penetrates an insulating layer (e.g., the first to third gate insulating layers GI1, GI2, and GI3 and the first and second interlayer insulating layers ILD1 and ILD2) disposed therebelow.

The second source electrode SE2 may be electrically connected to the second source area of the second active pattern ACT2 through a third contact hole that penetrates an insulating layer (e.g., the third gate insulating layer GI3 and the second interlayer insulating layer ILD2) disposed therebelow. The second drain electrode DE2 may be electrically connected to the second drain area of the second active pattern ACT2 through a fourth contact hole that penetrates an insulating layer (e.g., the third gate insulating layer GI3 and the second interlayer insulating layer ILD2) disposed therebelow.

Accordingly, the first transistor TR1 defined by the first lower electrode BME1, the first active pattern ACT1, the first gate electrode GE1, the first source electrode SE1, and the first drain electrode DE1 and the second transistor TR2 defined by the second lower electrode BME2, the second active pattern ACT2, the second gate electrode GE2, the second source electrode SE2, and the second drain electrode DE2 may be disposed in the display area DA on the substrate SUB.

The first via insulating layer VIA1 may be disposed on the first and second source electrodes SE1 and SE2 and the first and second drain electrodes DE1 and DE2, and may cover the first and second source electrodes SE1 and SE2 and the first and second drain electrodes DE1 and DE2. The first via insulating layer VIA1 may include an organic insulating material, such as a phenol resin, an acrylic resin, a polyimide resin, a polyamide resin, a siloxane resin, an epoxy resin, or the like.

The connection electrode LCE may be disposed on the first via insulating layer VIA1. The connection electrode LCE may be electrically connected to the first source electrode SE1 or the first drain electrode DE1 through a contact hole that penetrates an insulating layer (e.g., the first via insulating layer VIA1) disposed therebelow. Accordingly, the connection electrode LCE may electrically connect the first transistor TR1 and the light emitting element LE. The connection electrode LCE may include a conductive material.

The second via insulating layer VIA2 may be disposed on the connection electrode LCE, and may cover the connection electrode LCE. The second via insulating layer VIA2 may include an organic insulating material.

The pixel electrode PE may be disposed on the second via insulating layer VIA2. The pixel electrode PE may be electrically connected to the connection electrode LCE through a contact hole that penetrates an insulating layer (e.g., the second via insulating layer VIA2) disposed therebelow. The pixel electrode PE may include a conductive material. For example, the pixel electrode PE may function as the first electrode of the light emitting element LE of FIG. 3.

The pixel defining layer PDL may be disposed on the second via insulating layer VIA2. The pixel defining layer PDL may cover an edge portion of the pixel electrode PE, and may define an opening that exposes at least a portion of an upper surface of the pixel electrode PE. The pixel defining layer PDL may include an organic or inorganic insulating material.

The emission layer EL may be disposed on the pixel electrode PE. The emission layer EL may be disposed on the upper surface of the pixel electrode PE exposed by the pixel defining layer PDL. The emission layer EL may include a material that emits light of a predetermined color. For example, the emission layer EL may include a material that emits light in a red wavelength band, a green wavelength band, or a blue wavelength band, but embodiments are not limited thereto.

The common electrode CE may be disposed on the pixel defining layer PDL and the emission layer EL. The common electrode CE may include a conductive material. For example, the common electrode CE may function as the second electrode of the light emitting element LE of FIG. 3.

Accordingly, the light emitting element LE defined by the pixel electrode PE, the emission layer EL, and the common electrode CE may be disposed in the display area DA on the substrate SUB. The light emitting element LE may be electrically connected to the first transistor TR1, and may generate light corresponding to the driving current provided from the first transistor TR1.

The encapsulation layer TFE may be disposed on the common electrode CE. The encapsulation layer TFE may prevent or reduce impurities, moisture, or the like from penetrating into the light emitting element LE from the outside. The encapsulation layer TFE may include at least one inorganic encapsulation layer including an inorganic insulating material and at least one organic encapsulation layer including an organic insulating material.

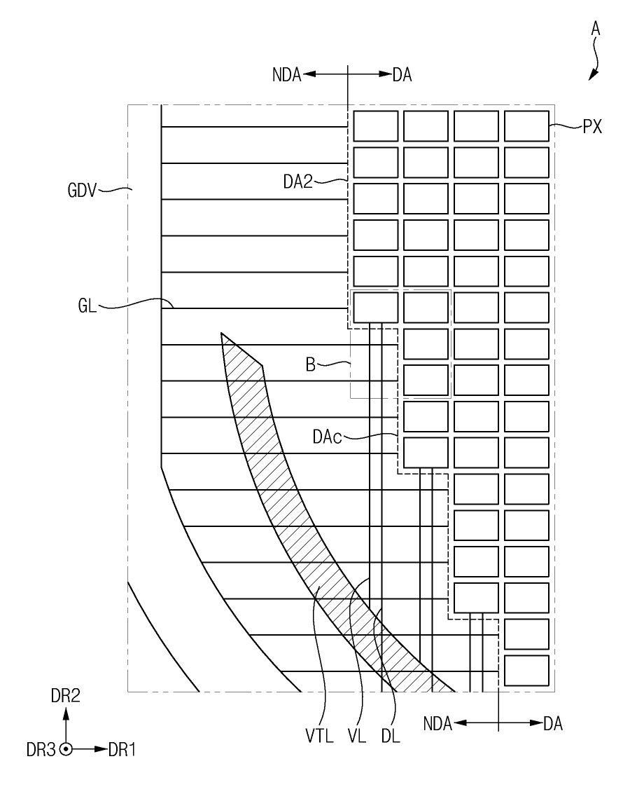

FIG. 5 is an enlarged plan view illustrating area A of FIG. 2. FIG. 5 may illustrate the pixels PX, the gate driver GDV, and the power transmission line VTL disposed in an area adjacent to the corner portion DAc.

Referring to FIGS. 2 and 5, in the corner portion DAc, the pixels PX may be disposed in a stepwise manner. The pixels PX may be disposed in a stepwise manner to define the corner portion DAc of the display area DA having a rounded planar shape.

The gate driver GDV may transmit the gate signals to the pixels PX through the gate lines GL. For example, the gate signals may include the first to fourth gate signals GW, GC, GI, and GB and the emission signal EM of FIG. 3. The data driver DDV may transmit the data voltages DATA of FIG. 3 to the pixels PX through the data lines DL.

An end portion of the power transmission line VTL may extend between the gate driver GDV and the corner portion DAc in a plan view. For example, the gate driver GDV and the power transmission line VTL may extend along the corner portion DAc. The power transmission line VTL may transmit the power voltages to the pixels PX through the power lines VL. For example, the power lines VL may include the first to fourth power lines VL1, VL2, VL3, and VL4 of FIG. 3, and the power voltages may include the first and second power voltages ELVDD and ELVSS and the first and second initialization voltages VINT and VAINT of FIG. 3.

FIG. 5 illustrates that the pixels PX are disposed in a stepwise manner by one pixel PX in the first direction DR1 and four pixels PX in the second direction DR2 in the corner portion DAc, but embodiments are not limited thereto. The number of pixels PX disposed in a stepwise manner in the corner portion DAc may vary depending on embodiments.

The structure in which the pixels PX disposed in the corner portion DAc connecting the first side D1 and the second side DA2 are connected to the gate driver GDV and the power transmission line VTL may be similar to and symmetrical to the structure in which the pixels PX disposed in the corner portion DAc connecting the first side DA1 and the fourth side DA4 are connected to the emission driver EDV and the power transmission line VTL.

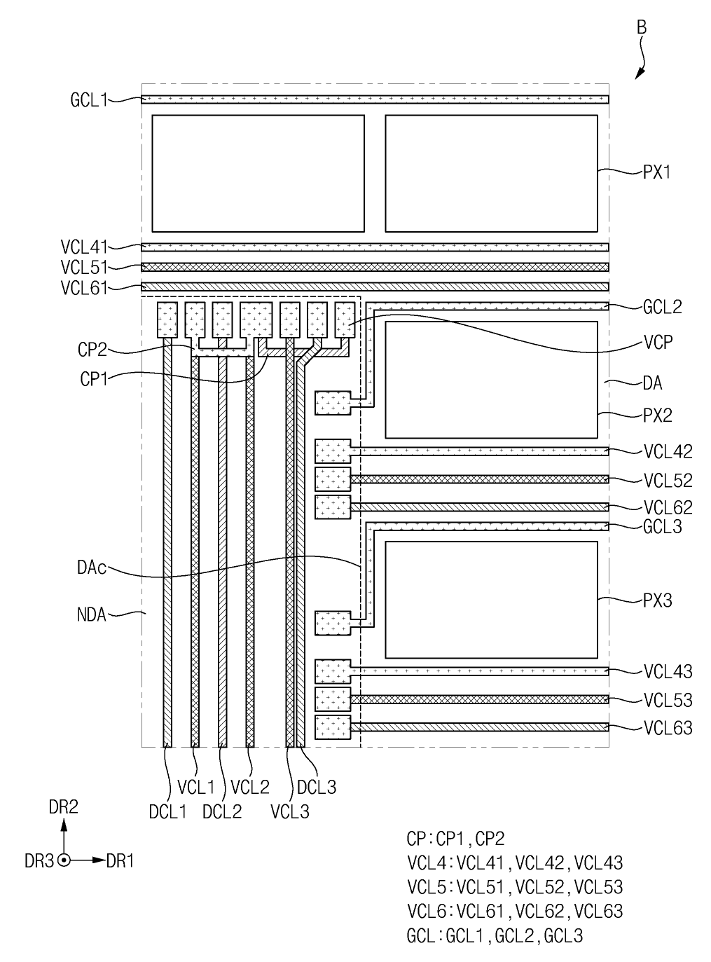

FIGS. 6 to 8 are enlarged plan views illustrating area B of FIG. 5. FIGS. 6 to 8 may illustrate an outermost area of the corner portion DAc.

Referring to FIGS. 2 to 4 and 6 to 8, the display device DD1 may include a plurality of lines for transmitting the data voltages DATA, the power voltages, and the gate signals GS to the pixels PX in the display area DA and the non-display area NDA.

In an embodiment, the display device DD1 may include a first data connection line DCL1, a second data connection line DCL2, a third data connection line DCL3, a first power connection line VCL1, a second power connection line VCL2, a third power connection line VCL3, a fourth power connection line VCL4, a fifth power connection line VCL5, a sixth power connection line VCL6, and gate connection lines GCL. For example, each of the first to third data connection lines DCL1, DCL2, and DCL3 and the first to third power connection lines VCL1, VCL2, and VCL3 may extend in the second direction DR2, and each of the fourth to sixth power connection lines VCL4, VCL5, and VCL6 and the gate connection lines GCL may extend in the first direction DR1.

The pixels PX may include first pixels PX1 disposed in a n-th row (where n is a natural number), second pixels PX2 disposed in a n+1-th row, and third pixels PX3 disposed in a n+2-th row. The first to third pixels PX1, PX2, and PX3 may be sequentially disposed in a direction opposite to the second direction DR2 in the display area DA. As the pixels PX are disposed in a stepwise manner in the corner portion DAc, the first pixels PX1 may be disposed to protrude further in a direction opposite to the first direction DR1 than the second and third pixels PX2 and PX3.

The first to third data connection lines DCL1, DCL2, and DCL3 may be electrically connected to the data driver DDV, and may be included in the data lines DL. The first to third data connection lines DCL1, DCL2, and DCL3 may transmit the data voltages DATA to the pixels PX. The first to third data connection lines DCL1, DCL2, and DCL3 may be disposed in the non-display area NDA.

In an embodiment, the first data connection line DCL1, the third data connection line DCL3, and the capacitor electrode CAPE may be disposed in a same layer, and the second data connection line DCL2 and the first gate electrode GE1 may be disposed in a same layer. The first data connection line DCL1, the third data connection line DCL3, and the capacitor electrode CAPE may include a same material and may be formed through a same process. The second data connection line DCL2 and the first gate electrode GE1 may include a same material and may be formed through a same process. However, embodiments are not limited thereto, and the layers on which the first to third data connection lines DCL1, DCL2, and DCL3 are disposed may vary depending on embodiments.

The first to sixth power connection lines VCL1, VCL2, VCL3, VCL4, VCL5, and VCL6 may be electrically connected to the power transmission line VTL, and may be included in the power line VL. The first to sixth power connection lines VCL1, VCL2, VCL3, VCL4, VCL5, and VCL6 may transmit the power voltages to the pixels PX.

In an embodiment, the first power connection line VCL1 and the second power connection line VCL2 may receive the first power voltage ELVDD, and may transmit the first power voltage ELVDD to the pixels PX. The third power connection line VCL3 and the sixth power connection line VCL6 may receive the first initialization voltage VINT, and may transmit the first initialization voltage VINT to the pixels PX. The fourth power connection line VCL4 may receive the second power voltage ELVSS, and may transmit the second power voltage ELVSS to the pixels PX. The fifth power connection line VCL5 may receive the second initialization voltage VAINT, and may transmit the second initialization voltage VAINT to the pixels PX.

The first to third power connection lines VCL1, VCL2, and VCL3 may be disposed in the non-display area NDA, and the fourth to sixth power connection lines VCL4, VCL5, and VCL6 may be disposed in the display area DA. For example, the fourth to sixth power connection lines VCL4, VCL5, and VCL6 may extend from the display area DA to the non-display area NDA. For example, the fourth power connection line VCL4 may include a fourth-first power connection line VCL41, a fourth-second power connection line VCL42, and a fourth-third power connection line VCL43 that respectively transmit the power voltage to the first pixels PX1, the second pixels PX2, and the third pixels PX3. The fifth power connection line VCL5 may include a fifth-first power connection line VCL51, a fifth-second power connection line VCL52, and a fifth-third power connection line VCL53 that respectively transmit the power voltage to the first pixels PX1, the second pixels PX2, and the third pixels PX3. The sixth power connection line VCL6 may include a sixth-first power connection line VCL61, a sixth-second power connection line VCL62, and a sixth-third power connection line VCL63 that respectively transmit the power voltage to the first pixels PX1, the second pixels PX2, and the third pixels PX3.

In an embodiment, referring to FIG. 6, the first power connection line VCL1, the second power connection line VCL2, the third power connection line VCL3, and the second gate electrode GE2 may be disposed in a same layer. The first power connection line VCL1, the second power connection line VCL2, the third power connection line VCL3, and the second gate electrode GE2 may include a same material and may be formed through a same process.

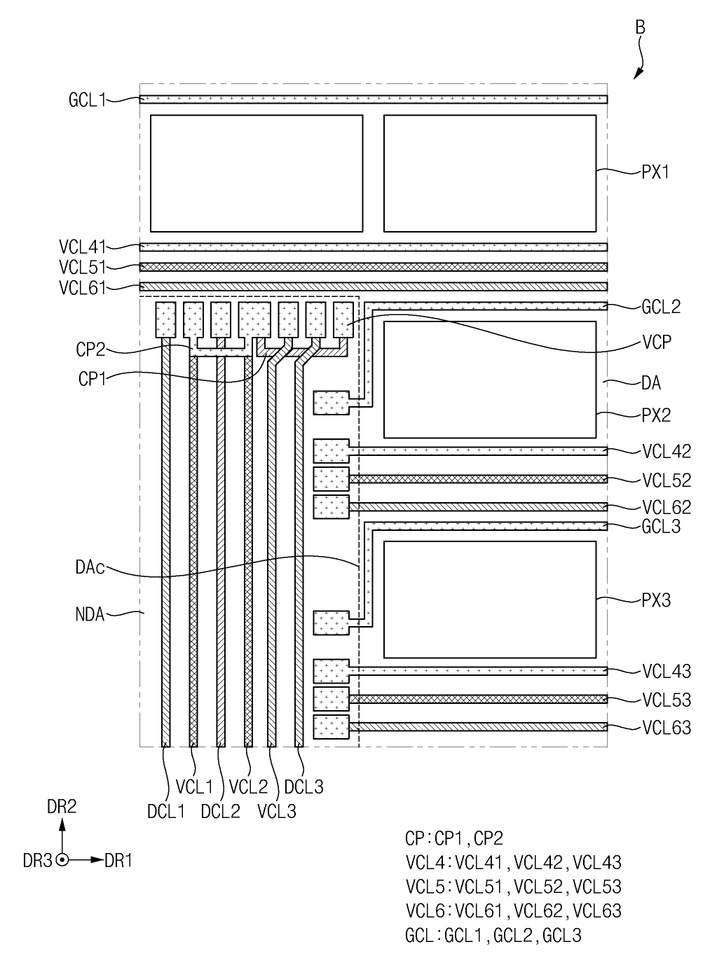

In an embodiment, referring to FIG. 7, the first power connection line VCL1, the second power connection line VCL2, the third power connection line VCL3, and the capacitor electrode CAPE may be disposed in a same layer. The first power connection line VCL1, the second power connection line VCL2, the third power connection line VCL3, and the capacitor electrode CAPE may include a same material and may be formed through a same process.

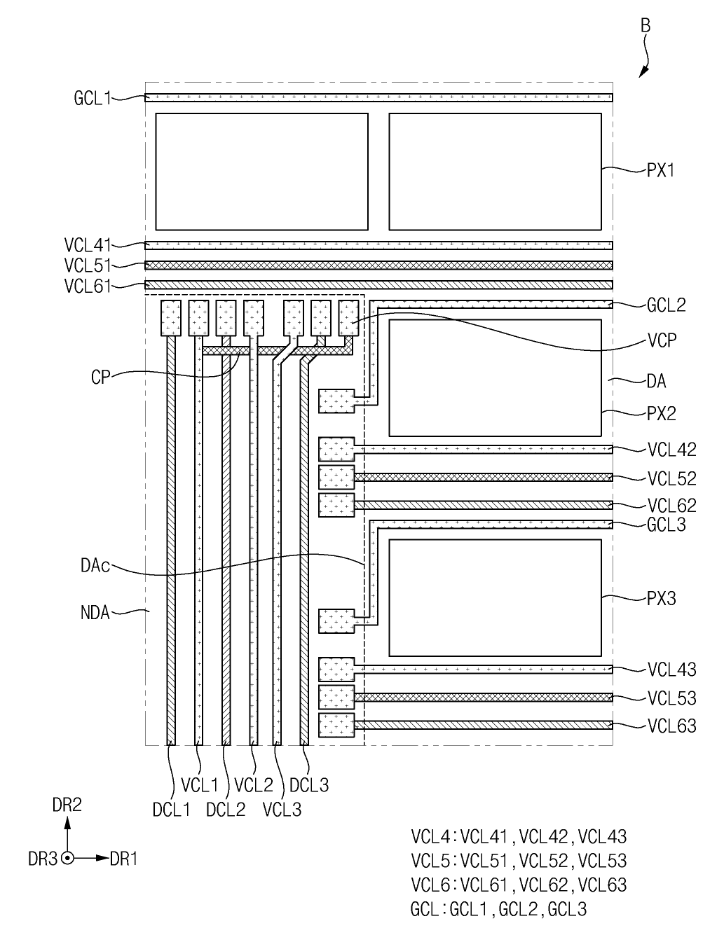

In an embodiment, referring to FIG. 8, the first power connection line VCL1, the second power connection line VCL2, the third power connection line VCL3, and the first source electrode SE1 may be disposed in a same layer. The first power connection line VCL1, the second power connection line VCL2, the third power connection line VCL3, and the first source electrode SE1 may include a same material and may be formed through a same process.

In an embodiment, the fourth power connection line VCL4 and the first source electrode SE1 may be disposed in a same layer, the fifth power connection line VCL5 and the second gate electrode GE2 may be disposed in a same layer, and the sixth power connection line VCL6 and the capacitor electrode CAPE may be disposed in a same layer. The fourth power connection line VCL4 and the first source electrode SE1 may include a same material and may be formed through a same process. The fifth power connection line VCL5 and the second gate electrode GE2 may include a same material and may be formed through a same process. The sixth power connection line VCL6 and the capacitor electrode CAPE may include a same material and may be formed through a same process. However, embodiments are not limited thereto, and the layers on which the first to sixth power connection lines VCL1, VCL2, VCL3, VCL4, VCL5, and VCL6 are disposed may vary depending on embodiments.

In an embodiment, the display device DD1 may include a connection pattern CP that electrically connects the first power connection line VCL1 and the second power connection line VCL2. In addition, the display device DD1 may further include a power connection pattern VCP electrically connected to the first power connection line VCL1 and the second power connection line VCL2, and the connection pattern CP may electrically connect the first power connection line VCL1, the second power connection line VCL2, and the power connection pattern VCP. The connection pattern CP may overlap each of the first power connection line VCL1, the second power connection line VCL2, and the power connection pattern VCP in a plan view. The connection pattern CP may be connected to each of end portions of the first power connection line VCL1 and the second power connection line VCL2 that transmit a same power voltage (e.g., the first power voltage ELVDD).

Hereinafter, the connection pattern CP will be described with reference to FIGS. 6 and 7.

In an embodiment, the connection pattern CP may be defined as a plurality of patterns. The connection pattern CP may include a first connection pattern CP1 and a second connection pattern CP2. For example, the first connection pattern CP1 may be connected to the power connection pattern VCP through a contact hole, and the second connection pattern CP2 may be connected to the first power connection line VCL1, the second power connection line VCL2, and the first connection pattern CP1 through contact holes, respectively. The first connection pattern CP1 and the second connection pattern CP2 may be disposed in different layers.

In an embodiment, the first connection pattern CP1 and the first gate electrode GE1 may be disposed in a same layer, and the second connection pattern CP2 and the first source electrode SE1 may be disposed in a same layer. The first connection pattern CP1 and the first gate electrode GE1 may include a same material and may be formed through a same process. The second connection pattern CP2 and the first source electrode SE1 may include a same material and may be formed through a same process. However, embodiments are not limited thereto, and the layers on which the first and second connection patterns CP1 and CP2 are disposed may vary depending on embodiments.

In an embodiment, each of the first connection pattern CP1 and the second connection pattern CP2 may extend in a direction away from the pixel PX adjacent to the first connection pattern CP1 and the second connection pattern CP2 in the second direction DR2. Each of the first connection pattern CP1 and the second connection pattern CP2 may have a shape that extends in a direction away from the first pixel PX1 (e.g., a first pixel PX1 disposed at the outermost edge of the corner portion DAc). Each of the first connection pattern CP1 and the second connection pattern CP2 may have a shape curved in a direction opposite to the second direction DR2. For example, each of the first connection pattern CP1 and the second connection pattern CP2 may have a U-shaped planar shape. For example, in a plan view, the first connection pattern CP1 may at least partially overlap each of the third power connection line VCL3 and the third data connection line DCL3, and the second connection pattern CP2 may at least partially overlap each of the first power connection line VCL1, the second power connection line VCL2, and the second data connection line DCL2.

As the connection pattern CP electrically connecting the first power connection line VCL1 and the second power connection line VCL2 is formed to be away from the first pixel PX1, an introduction of a pulse potential caused by electrostatic discharge generated in the first to third power connection lines VCL1, VCL2, and VCL3 into the first pixels PX1 may be reduced. In addition, as the connection pattern CP is defined by the first and second connection patterns CP1 and CP2 and the first and second connection patterns CP1 and CP2 are formed in different layers spaced apart in the third direction DR3, the introduction of the pulse potential caused by electrostatic discharge generated in the first to third power connection lines VCL1, VCL2, and VCL3 into the first pixels PX1 may be further reduced.

Hereinafter, the connection pattern CP will be described with reference to FIG. 8.

In an embodiment, the connection pattern CP may be defined as a single pattern. For example, the connection pattern CP may be connected to the first power connection line VCL1, the second power connection line VCL2, and the power connection pattern VCP through contact holes, respectively.

In an embodiment, the connection pattern CP and the second gate electrode GE2 may be disposed in a same layer. The connection pattern CP and the second gate electrode GE2 may include a same material and may be formed through a same process. However, embodiments are not limited thereto, and the layer on which the connection pattern CP is disposed may vary depending on embodiment.

In an embodiment, the connection pattern CP may extend in a direction away from the pixel PX adjacent to the connection pattern CP in the second direction DR2. The connection pattern CP may have a shape that extends in a direction away from the first pixel PX1 (e.g., the first pixel PX1 disposed at the outermost edge of the corner portion DAc). The connection pattern CP may have a shape curved in the direction opposite to the second direction DR2. For example, the connection pattern CP may have a W-shaped planar shape. For example, in a plan view, the connection pattern CP may at least partially overlap each of the first power connection line VCL1, the second power connection line VCL2, the third power connection line VCL3, the second data connection line DCL2, and the third data connection line DCL3.

As the connection pattern CP electrically connecting the first power connection line VCL1 and the second power connection line VCL2 is formed to be away from the first pixel PX1, the introduction of the pulse potential caused by electrostatic discharge generated in the first to third power connection lines VCL1, VCL2, and VCL3 into the first pixels PX1 may be reduced.

Referring again to FIGS. 2 to 4 and 6 to 8, the first to third power connection lines VCL1, VCL2, and VCL3 and the first to third data connection lines DCL1, DCL2, and DCL3 may be disposed adjacent to the corner portion DAc where the pixels PX are disposed in a stepwise manner. The first to third power connection lines VCL1, VCL2, and VCL3 and the first to third data connection lines DCL1, DCL2, and DCL3 may extend to the outermost edge of the corner portion DAc. A portion (e.g., an end portion) of each of the first to third power connection lines VCL1, VCL2, and VCL3 and the first to third data connection lines DCL1, DCL2, and DCL3 may be disposed on a step difference in a plan view of the non-display area NDA, which is formed as the pixels PX are disposed in a stepwise manner in the corner portion DAc. The first to third power connection lines VCL1, VCL2, and VCL3 and the first to third data connection lines DCL1, DCL2, and DCL3 may extend to an area where the first pixels PX1 protrude further than the second and third pixels PX2 and PX3.

An end portion of the first power connection line VCL1, an end portion of the second power connection line VCL2, an end portion of the third power connection line VCL3, an end portion of the first data connection line DCL1, an end portion of the second data connection line DCL2, an end portion of the third data connection line DCL3, the power connection pattern VCP, and the second pixels PX2 may be disposed in a same row (i.e., the n+1-th row). The end portion of the first data connection line DCL1, the end portion of the first power connection line VCL1, the end portion of the second data connection line DCL2, the end portion of the second power connection line VCL2, the end portion of the third data connection line DCL3, the end portion of the third power connection line VCL3, the power connection pattern VCP, and the second pixels PX2 may be disposed in the first direction DR1.

In an embodiment, the first data connection line DCL1, the first power connection line VCL1, the second data connection line DCL2, the second power connection line VCL2, the third power connection line VCL3, and the third data connection line DCL3 may be sequentially disposed in the first direction DR1. However, embodiments are not limited thereto, and the arrangement of the lines may vary depending on embodiments.

The gate connection lines GCL may be electrically connected to the gate driver GDV, and may be included in the gate lines GL. The gate connection lines GCL may transmit the gate signals GS to the pixels PX. The gate connection lines GCL may be disposed in the display area DA. For example, the gate connection lines GCL may extend from the display area DA to the non-display area NDA. For example, the gate connection lines GCL may include a first gate connection line GCL1, a second gate connection line GCL2, and a third gate connection line GCL3 that respectively transmit the gate signals GS to the first pixels PX1, the second pixels PX2, and the third pixels PX3. The gate signals GS may include the first to fourth gate signals GW, GC, GI, and GB and the emission signal EM, and the gate connection lines GCL may include a plurality of lines that transmit the first to fourth gate signals GW, GC, GI, and GB and the emission signal EM to the pixels PX.

In an embodiment, the gate connection line GCL and the first source electrode SE1 may be disposed in a same layer. The gate connection line GCL and the first source electrode SE1 may include a same material and may be formed through a same process. However, embodiments are not limited thereto, and the layer on which the gate connection line GCL is disposed may vary depending on embodiments.

The display device DD1 according to an embodiment may include the first to third power connection lines VCL1, VCL2, and VCL3 that transmit the power voltages to the pixels PX and the connection pattern CP that electrically connects the first power connection line VCL1 and the second power connection line VCL2. As the connection pattern CP extends in a direction away from the pixels PX disposed in the corner portion DAc, the introduction of the pulse potential caused by electrostatic discharge generated in the first to third power connection lines VCL1, VCL2, and VCL3 into the pixels PX may be reduced. Accordingly, a malfunction of the pixel driving circuit PC may be reduced, and a display quality of the display device DD1 may be improved.

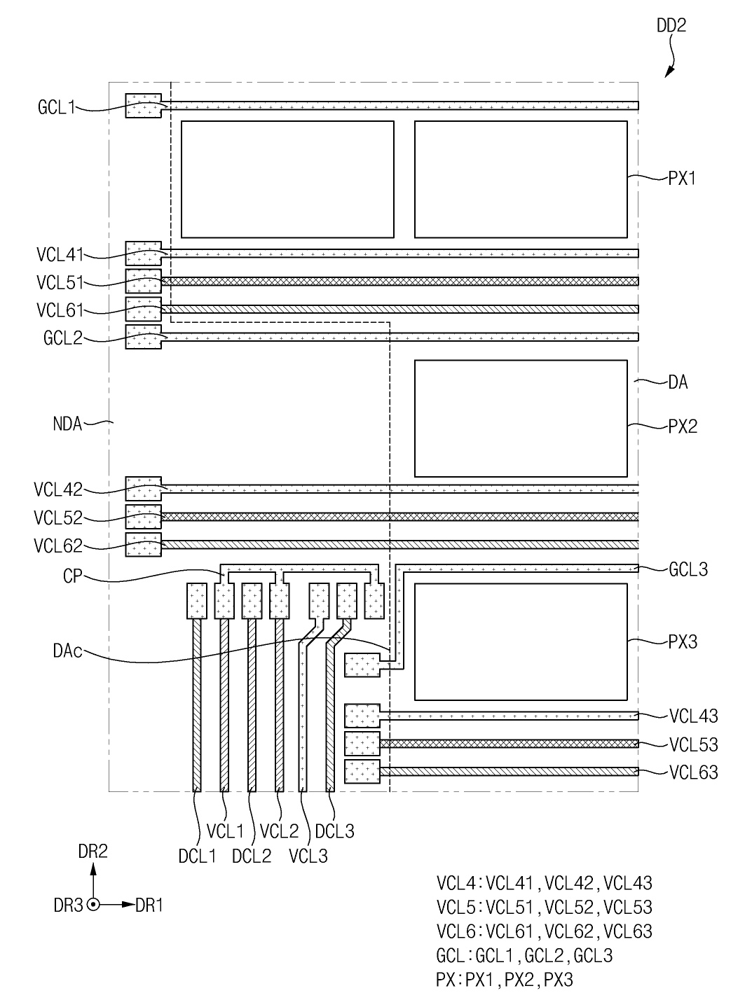

FIG. 9 is a plan view illustrating a display device according to an embodiment. FIG. 9 may correspond to FIGS. 6 to 8. FIG. 9 may illustrate an outermost area of the corner portion DAc.

Hereinafter, descriptions overlapping with the display device DD1 described above with reference to FIGS. 1 to 8 may be omitted or simplified.

Referring to FIG. 9, a display device DD2 may include the first to third data connection lines DCL1, DCL2, and DCL3 that transmit the data voltages to the pixels PX, the first to sixth power connection lines VCL1, VCL2, VCL3, VCL4, VCL5, and VCL6 that transmit the power voltages to the pixels PX, the gate connection lines GCL that transmit the gate signals to the pixels PX, and a connection pattern CP that electrically connects the first and second power connection lines VCL1 and VCL2.

For example, each of the first to third data connection lines DCL1, DCL2, and DCL3 and the first to third power connection lines VCL1, VCL2, and VCL3 may extend in the second direction DR2, and each of the fourth to sixth power connection lines VCL4, VCL5, and VCL6 and the gate connection lines GCL may extend in the first direction DR1.

The pixels PX may include the first pixels PX1 disposed in the n-th row, the second pixels PX2 disposed in the n+1-th row, and the third pixels PX3 disposed in the n+2-th row. The pixels PX may be disposed in a stepwise manner in the corner portion DAc of the display area DA, and the first pixels PX1 may be disposed to protrude further in the direction opposite to the first direction DR1 than the second and third pixels PX2 and PX3.

The first to third data connection lines DCL1, DCL2, and DCL3 and the first to third power connection lines VCL1, VCL2, and VCL3 may be disposed in the non-display area NDA, and the fourth to sixth power connection lines VCL4, VCL5, and VCL6 and the gate connection lines GCL may extend from the display area DA to the non-display area NDA.

The first power connection line VCL1 and the second power connection line VCL2 may transmit the first power voltage, the third power connection line VCL3 and the sixth power connection line VCL6 may transmit the first initialization voltage, the fourth power connection line VCL4 may transmit the second power voltage, and the fifth power connection line VCL5 may transmit the second initialization voltage.

In an embodiment, an end portion of the first power connection line VCL1, an end portion of the second power connection line VCL2, an end portion of the third power connection line VCL3, an end portion of the first data connection line DCL1, an end portion of the second data connection line DCL2, an end portion of the third data connection line DCL3, and the third pixels PX3 may be disposed in a same row (i.e., the n+2-th row). The first to third power connection lines VCL1, VCL2, and VCL3 and the first to third data connection lines DCL1, DCL2, and DCL3 may extend from the non-display area NDA to the row (i.e., the n+2-th row) in which the third pixels PX3 are disposed, and may not be disposed in the row (i.e., the n+1-th row) in which the second pixels PX2 are disposed. The first to third power connection lines VCL1, VCL2, and VCL3 and the first to third data connection lines DCL1, DCL2, and DCL3 may be spaced apart from the row in which the second pixels PX2 are disposed. The end portion of the first data connection line DCL1, the end portion of the first power connection line VCL1, the end portion of the second data connection line DCL2, the end portion of the second power connection line VCL2, the end portion of the third data connection line DCL3, the end portion of the third power connection line VCL3, and the third pixels PX3 may be disposed in the first direction DR1.

That is, the first to third power connection lines VCL1, VCL2, and VCL3 and the first to third data connection lines DCL1, DCL2, and DCL3 may be spaced apart from the pixels PX (e.g., the first pixels PX1) adjacent in the second direction DR2 by one pixel row. As the first to third power connection lines VCL1, VCL2, and VCL3 are formed to be spaced apart from the first pixels PX1, the introduction of the pulse potential caused by electrostatic discharge generated in the first to third power connection lines VCL1, VCL2, and VCL3 into the first pixels PX1 may be reduced.

The fourth power connection line VCL4 may include the fourth-first power connection line VCL41, the fourth-second power connection line VCL42, and the fourth-third power connection line VCL43 that respectively transmit the power voltage to the first pixels PX1, the second pixels PX2, and the third pixels PX3. The fifth power connection line VCL5 may include the fifth-first power connection line VCL51, the fifth-second power connection line VCL52, and the fifth-third power connection line VCL53 that respectively transmit the power voltage to the first pixels PX1, the second pixels PX2, and the third pixels PX3. The sixth power connection line VCL6 may include the sixth-first power connection line VCL61, the sixth-second power connection line VCL62, and the sixth-third power connection line VCL63 that respectively transmit the power voltage to the first pixels PX1, the second pixels PX2, and the third pixels PX3.

In an embodiment, the fourth-first power connection line VCL41, the fourth-second power connection line VCL42, the fifth-first power connection line VCL51, the fifth-second power connection line VCL52, the sixth-first power connection line VCL61, and the sixth-second power connection line VCL62 may extend further in the direction opposite to the first direction DR1 than the fourth-third power connection line VCL43, the fifth-third power connection line VCL53, and the sixth-third power connection line VCL63. An end portion of the fourth-first power connection line VCL41, an end portion of the fifth-first power connection line VCL51, an end portion of the sixth-first power connection line VCL61, an end portion of the fourth-second power connection line VCL42, an end portion of the fifth-second power connection line VCL52, and an end portion of the sixth-second power connection line VCL62 may be disposed in the second direction DR2. An end portion of the fourth-third power connection line VCL43, an end portion of the fifth-third power connection line VCL53, and an end portion of the sixth-third power connection line VCL63 may be disposed in the second direction DR2. A column in which the end portion of the fourth-first power connection line VCL41, the end portion of the fifth-first power connection line VCL51, the end portion of the sixth-first power connection line VCL61, the end portion of the fourth-second power connection line VCL42, the end portion of the fifth-second power connection line VCL52, and the end portion of the sixth-second power connection line VCL62 are disposed may be spaced apart in the first direction DR1 from a column in which the end portion of the fourth-third power connection line VCL43, the end portion of the fifth-third power connection line VCL53, and the end portion of the sixth-third power connection line VCL63 are disposed.

The fourth-second power connection line VCL42, the fifth-second power connection line VCL52, and the sixth-second power connection line VCL62 may extend further to the non-display area NDA than the fourth-third power connection line VCL43, the fifth-third power connection line VCL53, and the sixth-third power connection line VCL63. In an embodiment, the fourth-second power connection line VCL42, the fifth-second power connection line VCL52, and the sixth-second power connection line VCL62 electrically connected to the second pixels PX2 may extend by one pixel column further than the fourth-third power connection line VCL43, the fifth-third power connection line VCL53, and the sixth-third power connection line VCL63 electrically connected to the third pixels PX3.

The gate connection lines GCL may include may include the first gate connection line GCL1, the second gate connection line GCL2, and the third gate connection line GCL3 that respectively transmit the gate signals to the first pixels PX1, the second pixels PX2, and the third pixels PX3.

In an embodiment, the first gate connection line GCL1 and the second gate connection line GCL2 may extend further in the direction opposite to the first direction DR1 than the third gate connection line GCL3. An end portion of the first gate connection line GCL1 and an end portion of the second gate connection line GCL2 may be disposed in the second direction DR2. A column in which an end portion of the third gate connection line GCL3 is disposed may be spaced apart in the first direction DR1 from a column in which the end portion of the first gate connection line GCL1 and the end portion of the second gate connection line GCL2 are disposed.

The second gate connection line GCL2 may extend further to the non-display area NDA than the third gate connection line GCL3. In an embodiment, the second gate connection line GCL2 electrically connected to the second pixels PX2 may extend by one pixel column further than the third gate connection line GCL3 electrically connected to the third pixels PX3.

The connection pattern CP may be connected to the end portion of the first power connection line VCL1 and the end portion of the second power connection line VCL2 through contact holes, respectively. In an embodiment, the connection pattern CP may extend in a direction closer to the pixels PX adjacent in the second direction DR2. The connection pattern CP may have a shape that extends in a direction closer to the first pixels PX1 (e.g., the first pixel PX1 disposed at the outermost edge of the corner portion DAc). The connection pattern CP may have a shape curved in the second direction DR2. For example, the connection pattern CP may have an M-shaped planar shape. For example, the connection pattern CP may not overlap the second data connection line DCL2, the third data connection line DCL3, and the third power connection line VCL3 in a plan view.

The display device DD2 according to an embodiment may include the first to third power connection lines VCL1, VCL2, and VCL3 that transmit the power voltage to the pixels PX. As the first to third power connection lines VCL1, VCL2, and VCL3 are disposed to be spaced apart from the pixels PX disposed in the corner portion DAc, the introduction of the pulse potential caused by electrostatic discharge generated in the first to third power connection lines VCL1, VCL2, and VCL3 into the pixels PX may be reduced. Accordingly, the malfunction of the pixel driving circuit may be reduced, and the display quality of the display device DD2 may be improved.

FIG. 10 is a plan view illustrating a display device according to an embodiment. FIG. 10 may correspond to FIGS. 6 to 8. FIG. 10 may illustrate an outermost area of the corner portion DAc.

A display device DD3 described below with reference to FIG. 10 may be a display device that combines the structures of the display devices DD1 and DD2 described above. Hereinafter, descriptions overlapping with the display device DD1 described above with reference to FIGS. 1 to 8 and the display device DD2 described above with reference to FIG. 9 may be omitted or simplified.

Referring to FIG. 10, the display device DD3 may include the first to third data connection lines DCL1, DCL2, and DCL3 that transmit the data voltages to the pixels PX, the first to sixth power connection lines VCL1, VCL2, VCL3, VCL4, VCL5, and VCL6 that transmit the power voltages to the pixels PX, the gate connection lines GCL that transmit the gate signals to the pixels PX, and the connection pattern CP that electrically connects the first and second power connection lines VCL1 and VCL2.

The pixels PX may include the first pixels PX1 disposed in the n-th row, the second pixels PX2 disposed in the n+1-th row, and the third pixels PX3 disposed in the n+2-th row. The pixels PX may be disposed in a stepwise manner in the corner portion DAc of the display area DA, and the first pixels PX1 may be disposed to protrude further in the direction opposite to the first direction DR1 than the second and third pixels PX2 and PX3.

The first to third data connection lines DCL1, DCL2, and DCL3 and the first to third power connection lines VCL1, VCL2, and VCL3 may be disposed in the non-display area NDA, and the fourth to sixth power connection lines VCL4, VCL5, and VCL6 and the gate connection lines GCL may extend from the display area DA to the non-display area NDA.

In an embodiment, the first to third power connection lines VCL1, VCL2, and VCL3 and the first to third data connection lines DCL1, DCL2, and DCL3 may be disposed in a row (i.e., the n+2-th row) in which the third pixels PX3 are disposed, and may not be disposed in a row (i.e., the n+1-th row) in which the second pixels PX2 are disposed. That is, the first to third power connection lines VCL1, VCL2, and VCL3 and the first to third data connection lines DCL1, DCL2, and DCL3 may be disposed to be spaced apart from the first pixels PX1 by one pixel row.

The fourth power connection line VCL4 may include the fourth-first power connection line VCL41, the fourth-second power connection line VCL42, and the fourth-third power connection line VCL43 that respectively transmit the power voltage to the first pixels PX1, the second pixels PX2, and the third pixels PX3. The fifth power connection line VCL5 may include the fifth-first power connection line VCL51, the fifth-second power connection line VCL52, and the fifth-third power connection line VCL53 that respectively transmit the power voltage to the first pixels PX1, the second pixels PX2, and the third pixels PX3. The sixth power connection line VCL6 may include the sixth-first power connection line VCL61, the sixth-second power connection line VCL62, and the sixth-third power connection line VCL63 that respectively transmit the power voltage to the first pixels PX1, the second pixels PX2, and the third pixels PX3. The gate connection lines GCL may include the first gate connection line GCL1, the second gate connection line GCL2, and the third gate connection line GCL3 that respectively transmit the gate signals to the first pixels PX1, the second pixels PX2, and the third pixels PX3.

In an embodiment, the fourth-first power connection line VCL41, the fourth-second power connection line VCL42, the fifth-first power connection line VCL51, the fifth-second power connection line VCL52, the sixth-first power connection line VCL61, the sixth-second power connection line VCL62, the first gate connection line GCL1, and the second gate connection line GCL2 may extend further in the direction opposite to the first direction DR1 than the fourth-third power connection line VCL43, the fifth-third power connection line VCL53, the sixth-third power connection line VCL63, and the third gate connection line GCL3.

The fourth-second power connection line VCL42, the fifth-second power connection line VCL52, the sixth-second power connection line VCL62, and the second gate connection line GCL2 may extend further to the non-display area NDA than the fourth-third power connection line VCL43, the fifth-third power connection line VCL53, the sixth-third power connection line VCL63, and the third gate connection line GCL3. In an embodiment, the fourth-second power connection line VCL42, the fifth-second power connection line VCL52, the sixth-second power connection line VCL62, and the second gate connection line GCL2 electrically connected to the second pixels PX2 may extend by one pixel column further than the fourth-third power connection line VCL43, the fifth-third power connection line VCL53, the sixth-third power connection line VCL63, and the third gate connection line GCL3 electrically connected to the third pixels PX3.

The connection pattern CP may electrically connect the first power connection line VCL1, the second power connection line VCL2, and the power connection pattern VCP. The connection pattern CP may be connected to the end portion of the first power connection line VCL1 and the end portion of the second power connection line VCL2 through contact holes, respectively.

The connection pattern CP may be defined as a plurality of patterns or a single pattern. For example, the connection pattern CP may include a first connection pattern CP1 connected to the power connection pattern VCP, and a second connection pattern CP2 connected to the first power connection line VCL1, the second power connection line VCL2, and the first connection pattern CP1. The first connection pattern CP1 and the second connection pattern CP2 may be disposed in different layers.

In an embodiment, the connection pattern CP may extend in a direction away from the pixel PX adjacent to the connection pattern CP in the second direction DR2. The connection pattern CP may have a shape that extends in a direction away from the first pixel PX1 (e.g., the first pixel PX1 disposed at the outermost edge of the corner portion DAc). For example, the connection pattern CP may at least partially overlap each of the third power connection line VCL3, the second data connection line DCL2, and the third data connection line DCL3 in a plan view.

The display device DD3 according to an embodiment may include the first to third power connection lines VCL1, VCL2, and VCL3 that transmit the power voltages to the pixels PX and the connection pattern CP that electrically connects the first power connection line VCL1 and the second power connection line VCL2. As the connection pattern CP extends in a direction away from the pixels PX disposed at the outermost edge of the corner portion DAc and the first to third power connection lines VCL1, VCL2, and VCL3 are disposed to be spaced apart from the pixels PX disposed at the outermost edge of the corner portion DAc, the introduction of the pulse potential caused by electrostatic discharge generated in the first to third power connection lines VCL1, VCL2, and VCL3 into the pixels PX may be reduced. Accordingly, the malfunction of the pixel driving circuit may be reduced, and the display quality of the display device DD2 may be improved.

The display devices DD1, DD2, and DD3 according to embodiments may be applied to various electronic devices. The electronic device according to an embodiment may include the display device described above, and may further include modules or devices with additional functions other than the display device.

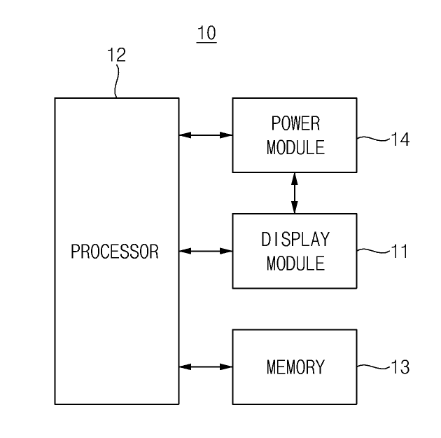

FIG. 11 is a block diagram illustrating an electronic device according to an embodiment.

Referring to FIG. 11, the electronic device 10 may include a display module 11, a processor 12, a memory 13, and a power module 14.

The processor 12 may include at least one of a central processing unit (“CPU”), an application processor (“AP”), a graphic processing unit (“GPU”), a communication processor (“CP”), an image signal processor (“ISP”), and a controller. The processor 12 may provide a control signal (e.g., the control signal CTRL of FIG. 1) and input image data (e.g., the input image data IDAT of FIG. 1) to a controller (e.g., the controller CON of FIG. 1) of the display module 11.

The memory 13 may store data information necessary for the operation of the processor 12 or the display module 11. When the processor 12 executes the application stored in the memory 13, the control signal and/or the input image data may be transmitted to the display module 11, and the display module 11 may process the received signal and output image information through a display screen.

The power module 14 may include a power supply module, such as a power adapter or a battery device, and a power conversion module which converts the power supplied by the power supply module to generate power required for the operation of the electronic device 10.

At least one of each component of the electronic device 10 described above may be included in the display device according to embodiments. In addition, some of the individual modules functionally included in one module may be included in the display device, and other portions may be provided separately from the display device. For example, the display device may include the display module 11, and the processor 12, the memory 13, and the power module 14 may be provided in the form of other devices within the electronic device 10 other than the display device.

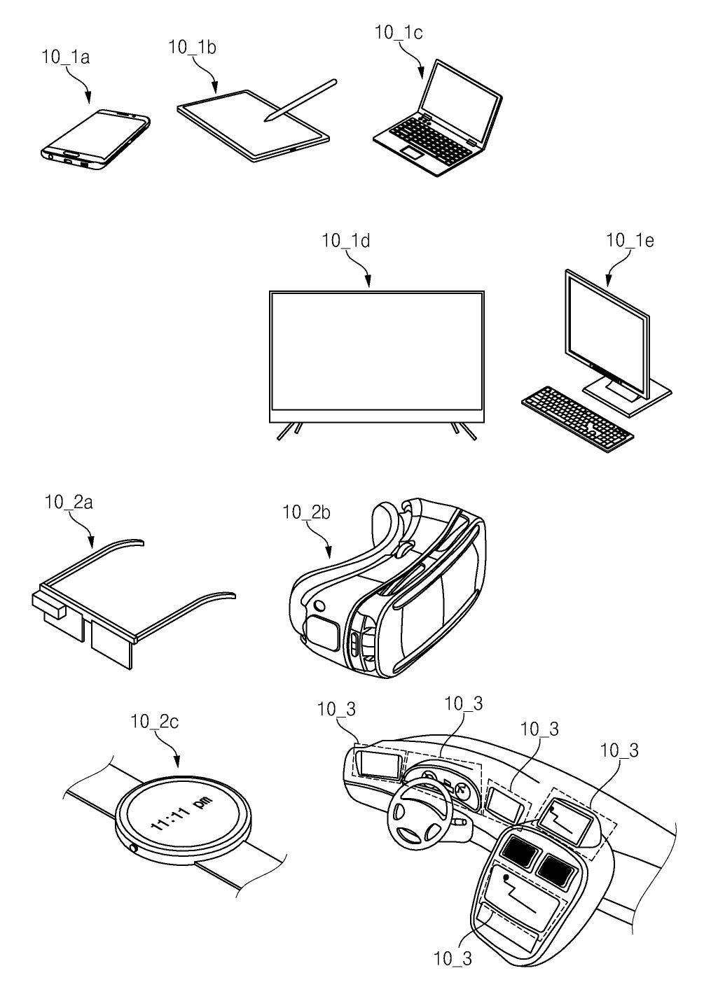

FIG. 12 is a schematic diagram illustrating electronic devices according to various embodiments.

Referring to FIG. 12, various electronic devices to which the display device according to embodiments are applied may include not only image display electronic devices such as a smartphone 10_1a, a tablet PC 10_1b, a laptop 10_1c, a TV 10_1d, and a desktop monitor 10_1e, but also wearable electronic devices including display modules, such as smart glasses 10_2a, a head-mounted display 10_2b, and a smart watch 10_2c, automotive electronic devices 10_3 including display modules, such as a dashboard of a car, a center fascia, a Center Information Display (“CID” disposed on a dashboard, and a room mirror display, or the like.

Although the present display device have been described wit reference to the embodiments shown in the drawings, these are merely exemplary, and those skilled in the art will understand that various modifications and equivalent other embodiments are possible therefrom. Therefore, the disclosed subject matter should not be limited to any single embodiment described herein.

Moreover, features of various embodiments of the disclosure may be combined partially or totally. As will be clearly appreciated by those skilled in the art, technically various interactions and operations are possible. In addition, various embodiments can be practiced individually or in combination.

What is claimed is:

1. A display device comprising:
a display panel comprising a display area and a non-display area adjacent to the display area, the display area including a corner portion;
a plurality of pixels disposed in the display area, the pixels being arranged in a grid defined by rows in a first direction and columns in a second direction crossing the first direction, a first set of pixels from among the plurality of pixels being arranged in the corner portion and being disposed in a stepwise manner to define a shape of the corner portion;
power connection lines disposed in the non-display area, the power connection lines extending in the second direction from the non-display area to the corner portion and being spaced apart from each other in the first direction, the power connection lines transmitting power voltages to the pixels; and
a connection pattern electrically connecting the power connection lines, the connection pattern extending in a direction away from the pixels adjacent to the connection pattern in the second direction.

2. The display device of claim 1, wherein the power connection lines include:
a first power connection line transmitting a first power voltage;
a second power connection line transmitting the first power voltage; and
a third power connection line transmitting a second power voltage, and
wherein the connection pattern is connected to the first power connection line and the second power connection line, and the connection pattern at least partially overlaps each of the first power connection line, the second power connection line, and the third power connection line.

3. The display device of claim 1, further comprising:
a power connection pattern adjacent to the power connection lines in the first direction,
wherein the connection pattern electrically connects the power connection lines to the power connection pattern.

4. The display device of claim 3, wherein the connection pattern includes a first connection pattern and a second connection pattern disposed in different layers.

5. The display device of claim 4, wherein the first connection pattern is connected to the power connection pattern, and
wherein the second connection pattern is connected to the power connection lines and the first connection pattern.

6. The display device of claim 4, wherein each of the pixels includes:
an active pattern;
a first gate electrode disposed on the active pattern;
a capacitor electrode disposed on the first gate electrode;
a second gate electrode disposed on the capacitor electrode; and
a source electrode disposed on the second gate electrode,
wherein the first connection pattern and the first gate electrode are disposed in a same layer, and
wherein the second connection pattern and the source electrode are disposed in a same layer.

7. The display device of claim 1, wherein each of the pixels includes:
an active pattern;
a first gate electrode disposed on the active pattern;
a capacitor electrode disposed on the first gate electrode;
a second gate electrode disposed on the capacitor electrode; and
a source electrode disposed on the second gate electrode, and
wherein the connection pattern and the source electrode are disposed in a same layer.

8. The display device of claim 1, wherein the connection pattern has a U-shaped curve in a direction opposite to the second direction.

9. The display device of claim 1, wherein, in the corner portion, the pixels include:
first pixels disposed in a first row;
second pixels disposed in a second row; and
third pixels disposed in a third row, and
wherein the power connection lines extend to the third row, and the power connection lines are spaced apart from the second row.

10. The display device of claim 9, further comprising:
gate connection lines extending in the first direction from the display area to the non-display area, the gate connection lines transmitting gate signals to the pixels,
wherein the gate connection lines include:
a first gate connection line electrically connected to the first pixels;
a second gate connection line electrically connected to the second pixels; and
a third gate connection line electrically connected to the third pixels, and
wherein the second gate connection line extends to the non-display area further than the third gate connection line extends to the non-display area.

11. The display device of claim 10, wherein an end portion of the first gate connection line and an end portion of the second gate connection line are disposed in the second direction.

12. A display device comprising:
a display panel comprising a display area and a non-display area adjacent to the display area, the display area including a corner portion;
a plurality of pixels disposed in the display area, the pixels being arranged in a grid defined by rows in a first direction and columns in a second direction crossing the first direction, a first set of pixels from among the plurality of pixels being arranged in the corner portion and being disposed in a stepwise manner to define a shape of the corner portion, wherein, in the corner portion, the pixels include:
first pixels disposed in a first row;
second pixels disposed in a second row; and
third pixels disposed in a third row; and
power connection lines disposed in the first direction in the non-display area, the power connection lines extending in the second direction from the non-display area to the third row of the corner portion, the power connection lines transmitting power voltages to the pixels.

13. The display device of claim 12, wherein the power connection lines are spaced apart from the second row.

14. The display device of claim 12, further comprising:
gate connection lines extending in the first direction from the display area to the non-display area, the gate connection lines transmitting gate signals to the pixels.

15. The display device of claim 14, wherein the gate connection lines include:
a first gate connection line electrically connected to the first pixels;
a second gate connection line electrically connected to the second pixels; and
a third gate connection line electrically connected to the third pixels, and
wherein the second gate connection line extends further to the non-display area than the third gate connection line.

16. The display device of claim 15, wherein an end portion of the first gate connection line and an end portion of the second gate connection line are disposed in the second direction.

17. The display device of claim 12, further comprising:
a connection pattern electrically connecting the power connection lines.

18. The display device of claim 17, wherein the connection pattern extends in a direction away from the pixels adjacent to the connection pattern in the second direction.

19. The display device of claim 17, wherein the power connection lines include:
a first power connection line transmitting a first power voltage;
a second power connection line transmitting the first power voltage; and
a third power connection line transmitting a second power voltage, and
wherein the connection pattern is connected to the first power connection line and the second power connection line, and the connection pattern at least partially overlaps each of the first power connection line, the second power connection line, and the third power connection line.

20. An electronic device comprising:
a display device including a plurality of pixels; and
a processor providing a control signal and input image data to the display device,
wherein the display device includes a display panel comprising:
a display area and a non-display area adjacent to the display area, the display area including a corner portion;
wherein the plurality of pixels are disposed in the display area, the pixels being arranged in a grid defined by rows in a first direction and columns in a second direction crossing the first direction, and a first set of pixels from among the plurality of pixels being arranged in the corner portion and being disposed in a stepwise manner to define a shape of the corner portion;
wherein power connection lines are disposed in the first direction in the non-display area, the power connection lines extending in the second direction from the non-display area to the corner portion, the power connection lines transmitting power voltages to the pixels; and
wherein a connection pattern electrically connects the power connection lines, the connection pattern extending in a direction away from the pixels adjacent to the connection pattern in the second direction.
